(19) United States
(12) Patent Application Publication
(10) Pub. No.: US 2017/0062056 A1
(43) Pub. Date: Mar. 2, 2017

(54) FORCED DISCHARGE CIRCUITS USING HIGH VOLTAGE BIAS AND ELECTRONIC DEVICES INCLUDING THE SAME

(71) Applicant: Samsung Electronics Co., Ltd., Suwon-si (KR)

(72) Inventors: IK-SUNG PARK, SEOUL (KR); HEE-YOUB KANG, SEOUL (KR); YOUNG-KEUN OH, SUWON-SI (KR); KYOUNG-EUN LEE, HWASEONG-SI (KR)

(21) Appl. No.: 15/202,116

(22) Filed: Jul. 5, 2016

(30) Foreign Application Priority Data
Aug. 28, 2015 (KR) 10-2015-0122089

(51) Int. Cl. G11C 16/10; G11C 16/30

(52) U.S. Cl. CPC G11C 16/10; G11C 16/30

(57) ABSTRACT

An apparatus includes a discharge control signal generator configured to be driven by a first voltage and to generate a discharge control signal in response to a power-off signal and a discharge circuit configured to discharge a power supply providing a second voltage less than the first voltage to a level of a ground voltage in response to the discharge control signal. The first voltage may be the highest voltage that is used in an electronic device including the apparatus, such as a program voltage of a flash memory or a delete voltage of a flash memory.

### CROSS-REFERENCE TO RELATED APPLICATION

This application claims the benefit of Korean Patent Application No. 10-2015-0122089, filed on Aug. 28, 2015, in the Korean Intellectual Property Office, the disclosure of which is incorporated herein in its entirety by reference.

### BACKGROUND

The inventive subject matter relates to an electronic devices and, more particularly, to forced discharge circuits for electronic devices.

A power supply of an electronic device may be intentionally turned off by a user or may be unexpectedly turned off regardless of the intention of a user. When the power supply of the electronic device is turned off, voltage levels of internal operating power supplies decrease. When the power supply of the electronic device is turned on, the voltage levels of the internal operating power supplies increase and circuits that are driven by the internal operating power supplies may stably operate. However, when a duration between power-off and power-on is relatively short, voltage levels of the internal operating power supplies may not decrease to a sufficiently low level and may increase again. Accordingly, the electronic device may malfunction.

### SUMMARY

Some embodiments provide an apparatus including a discharge control signal generator configured to be driven by a first voltage and to generate a discharge control signal in response to a power-off signal and a discharge circuit configured to discharge a power supply providing a second voltage less than the first voltage to a level of a ground voltage in response to the discharge control signal. The first voltage is the highest voltage that is used in an electronic device including the apparatus. For example, the first voltage may be a program voltage of a flash memory or a delete voltage of a flash memory. In some embodiments, the power-off signal may be activated when a main power supply voltage of the apparatus decreases to a predetermined voltage level or less.

In some embodiments, the discharge control signal generator may include a first resistor having a first terminal connected to a node having the first voltage and a first transistor connected between a second terminal of the first resistor and a node having the ground voltage and configured to be turned on or turned off in response to the power-off signal.

In some embodiments, the discharge control signal generator may include a first resistor having a first terminal connected to node having the first voltage, a first transistor connected between a second terminal of the first resistor and a node having the ground voltage and configured to be turned on or turned off in response to the power-off signal, and a second resistor connected between two terminals of the first transistor.

In some embodiments, the discharge circuit may include a first resistor having a first terminal connected to the power supply and a first transistor connected between a second terminal of the first resistor and a node having the ground voltage and configured to be turned on or turned off in response to the discharge control signal. The first resistor may be changeable to limit a current of the first transistor according to a voltage level of the first operating power supply.

In some embodiments, the power supply may include a first power supply and the discharge circuit may include a second resistor having a first terminal connected to a second power supply having a voltage greater than the voltage level of the first power supply and a second transistor connected between a second terminal of the second resistor and the node having the ground voltage and configured to be turned on or turned off in response to the discharge control signal. The apparatus may be configured to discharge the second power supply to the ground voltage before the first power supply.

Further embodiments provide an apparatus including a power management integrated circuit (PMIC) comprising at least one power supply configured to generate at least one power supply voltage from a main power supply and to generate a power-off signal when a level of a voltage of the main power supply decreases to a predetermined voltage level. The apparatus further includes a forced discharge circuit configured to be driven by a first voltage having a voltage level greater than the power supply voltage generated by the at least one power supply and discharge the at least one power supply to a level of a ground voltage in response to the power-off signal.

In some embodiments, the first voltage may be provided from the PMIC or is provided from an external source.

In some embodiments, the PMIC may compare a level of the voltage of the main power supply to a level of a reference voltage and generate the power-off signal based responsive to the comparing.

In further embodiments, the at least one power supply comprises a first power supply and the forced discharge circuit may include a discharge control signal generator configured to be driven by the first voltage and generate a discharge control signal in response to the power-off signal and a first discharge circuit configured to discharge the first power supply to the level of the ground voltage in response to the discharge control signal.

The discharge control signal generator may include a first resistor having a first terminal connected to a node having the first voltage and a first transistor connected between a second terminal of the first resistor and a node having the ground voltage and configured to be turned on or turned off in response to the power-off signal.

In some embodiments, the discharge control signal generator may include a first resistor having a first terminal connected to a node having the first voltage, a first transistor connected between a second terminal of the first resistor and a node having the ground voltage and configured to be turned on or turned off in response to the power-off signal, and a second resistor connected between two terminals of the first transistor.

The discharge circuit may include a first resistor having a first terminal connected to the power supply and a first transistor connected between a second terminal of the first resistor and a node having the ground voltage and configured to be turned on or turned off in response to the discharge control signal.

In some embodiments, the at least one power supply may include a second power supply producing a voltage greater than a voltage produced by the first power supply and the forced discharge circuit may further include a second discharge circuit configured to discharge the second power supply to the level of the ground voltage in response to the discharge control signal. The first and second power supplies may be discharged to the level of the ground voltage in an order of the second power supply and the first power supply.

In some embodiments, the apparatus may include a flash memory and the first voltage may be a delete voltage of the flash memory.

According to additional embodiments, an apparatus includes a discharge control signal generator comprising a first transistor having a first terminal coupled to a node having a first voltage, a second terminal coupled to a ground node, and a third terminal configured to receive a power-off signal and to control a current between the first and second terminals responsive thereto. The apparatus further includes a discharge circuit comprising a second transistor having a first terminal coupled to a power supply node having a second voltage less than the first voltage, a second terminal coupled to the ground node, and a third terminal coupled to the first terminal of the first transistor and configured to control a current between the first and second terminals of the second transistor.

In some embodiments, the first voltage may include a program voltage or a delete voltage of a flash memory apparatus.

The apparatus may further include a first resistor coupling the first terminal of the first transistor to the node having the first voltage and a second resistor coupling the first terminal of the second transistor to the power supply node. The first and second transistors may include respective first and second field effect transistors.

The discharge circuit may include a first discharge circuit, the power supply node may include a first power supply node, and the apparatus further may further include a second discharge circuit including a third transistor having a first terminal coupled to a second power supply node having a third voltage less than the second voltage, a second terminal coupled to the ground node and a third terminal coupled to the first terminal of the first transistor and configured to control a current between the first and second terminals of the third transistor. Responsive to assertion of the power-off signal, the second discharge circuit may discharge the second power supply node to a ground voltage faster than the first discharge circuit discharges the first power supply node to the ground voltage.

Still further embodiments provide an apparatus including a power management integrated circuit (PMIC) comprising a power supply configured to generate a power supply voltage from a main power supply and to generate a power-off signal when a voltage of the main power supply meets a predetermined criterion. The apparatus further includes a forced discharge circuit including a first transistor having a first terminal coupled to a node having a voltage greater than the power supply voltage, a second terminal coupled to a ground node, and a third terminal configured to receive the power-off signal and to control a current between the first and second terminals responsive thereto and a second transistor having a first terminal coupled to an output of the power supply, a second terminal coupled to the ground node, and a third terminal coupled to the first terminal of the first transistor and configured to control a current between the first and second terminals of the second transistor.

### BRIEF DESCRIPTION OF THE DRAWINGS

Exemplary embodiments of the inventive subject matter will be more clearly understood from the following detailed description taken in conjunction with the accompanying drawings in which:

FIG. 1 is a block diagram of an electronic device including a forced discharge circuit, according to some embodiments of the inventive subject matter;

FIG. 2 is a block diagram of a storage device including a forced discharge circuit, according to some embodiments of the inventive subject matter;

FIGS. 3A and 3B are diagrams for explaining a forced discharge circuit according to some embodiments of the inventive subject matter;

FIGS. 4A and 4B are diagrams for explaining a comparison example of the forced discharge circuit of FIG. 3A;

FIG. 5 is a diagram for explaining a forced discharge circuit according to some embodiments of the inventive subject matter;

FIG. 6 is a block diagram of a power management integrated circuit (PMIC) for generating a power-off signal, according to some embodiments of the inventive subject matter;

FIGS. 7A and 7B are diagrams for explaining a PMIC including a forced discharge circuit, according to some embodiments of the inventive subject matter;

FIG. 8 is a circuit diagram of the forced discharge circuit of FIG. 7;

FIG. 9 is a view of a memory card that is an application of a storage device including a forced discharge circuit, according to some embodiments of the inventive subject matter;

FIG. 10 is a block diagram of a server system using a solid state drive (SSD) that is an application of a storage device including a forced discharge circuit, according to some embodiments of the inventive subject matter;

FIG. 11 is a block diagram of an integrated circuit (IC) including a forced discharge circuit, according to some embodiments of the inventive subject matter;

FIG. 12 is a block diagram of a system-on chip (SoC) including a forced discharge circuit, according to some embodiments of the inventive subject matter;

FIG. 13 is a block diagram of a memory system including a forced discharge circuit, according to some embodiments of the inventive subject matter;

FIG. 14 is a block diagram of a display system including a forced discharge circuit, according to some embodiments of the inventive subject matter;

FIG. 15 is a block diagram of an image sensor including a forced discharge circuit, according to some embodiments of the inventive subject matter;

FIG. 16 is a block diagram of a mobile system using a forced discharge circuit according to some embodiments of the inventive subject matter; and

FIG. 17 is a block diagram of a computing system using a forced discharge circuit according to some embodiments of the inventive subject matter.

### DETAILED DESCRIPTION OF THE EMBODIMENTS

In order to fully understand the operational advantages of the inventive subject matter and the objects to be attained by the embodiments of the inventive subject matter, the accompanying drawings illustrating exemplary embodiments of the inventive subject matter and details described in the accompanying drawings should be referred to.

The inventive subject matter now will be described more fully hereinafter with reference to the accompanying drawings, in which elements of the inventive subject matter are shown. The inventive subject matter may, however, be embodied in many different forms and should not be construed as limited to the exemplary embodiments set forth herein. Rather, these embodiments are provided so that this disclosure will be thorough and complete, and will fully convey the scope of the inventive subject matter to one of ordinary skill in the art. As the inventive subject matter allows for various changes and numerous embodiments, particular embodiments will be illustrated in the drawings and described in detail in the written description. However, this is not intended to limit the inventive subject matter to particular modes of practice, and it is to be appreciated that all changes, equivalents, and substitutes that do not depart from the spirit and technical scope of the inventive subject matter are encompassed in the inventive subject matter. Like reference numerals refer to like elements throughout. Sizes of structures may be greater or less than real structures for clarity of the inventive subject matter.

The terminology used herein is for the purpose of describing particular embodiments only and is not intended to be limiting of exemplary embodiments. As used herein, the singular forms “a”, “an”, and “the” are intended to include the plural forms as well, unless the context clearly indicates otherwise. It will be further understood that the terms “comprises”, “comprising”, “includes”, and/or “including” when used herein, specify the presence of stated features, integers, steps, operations, elements, components, or combinations thereof but do not preclude the presence or addition of one or more other features, integers, steps, operations, elements, components, or combinations thereof.

Unless otherwise defined, all terms (including technical and scientific terms) used herein have the same meaning as commonly understood by one of ordinary skill in the art to which exemplary embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein. As used herein, the term “and/or” includes any and all combinations of one or more of the associated listed items.

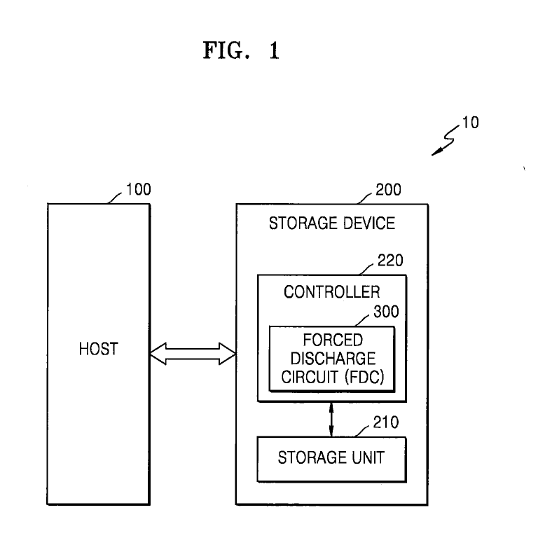

FIG. 1 is a block diagram of an electronic device 10 including a forced discharge circuit according to some embodiments of the inventive subject matter. The electronic device 10 includes a host 100 and a storage device 200. The host 100 may include a user device, such as a personal/portable computer, a tablet personal computer (PC), a personal digital assistant (PDA), a portable media player (PMP), a digital camera, or a camcorder. The host 100 stores data in the storage device 200 or reads data from the storage device 200 in response to an input or output request.

The host 100 may be connected to the storage device 200 via any of various interfaces, such as a universal serial bus (USB), a multimedia card (MMC), a peripheral component interconnection (PCI), a PCI-express (PCI-E), an advanced technology attachment (ATA), a serial-ATA, a parallel-ATA, a small computer small interface (SCSI), an enhanced small disk interface (ESDI), and an integrated drive electronics (IDE).

The storage device 200 may perform a write operation or a read operation in response to an input or output request of the host 200. The storage device 200 may form a solid state drive (SSD). According to some embodiments, the storage device 200 may be a personal computer card (personal computer memory card international association (PCMCIA)), a compact flash card (CF), a smart media card (SM or SMC), a memory stick, a multimedia card (MMC, eMMC, RS-MMC, or MMC-micro), a secure digital card (SD, miniSD, microSD, or SDHC), a universal flash storage (UFS), or a data server.

The storage device 200 may include a data storage unit 210 and a controller 220 that controls the overall operation of the data storage unit 210. The data storage unit 210 stores data during a write operation and outputs stored data during a read operation. The data storage unit 210 may include a non-volatile memory, such as a flash memory. According to some embodiments, the data storage unit 210 may include a NAND flash memory, a vertical NAND (VNAND) flash memory, a NOR flash memory, a resistive random access memory (RRAM), a phase-change memory (PRAM), a magnetoresistive random access memory (MRAM), a ferroelectric random access memory (FRAM), or a spin transfer torque random access memory (STT-RAM).

The host 100 may include a user space and a kernel space. The user space is an area in which a user application or an operating system is executed, and the kernel space is an area restrictively reserved for the execution of a kernel. The kernel space may include a file system, a device driver, and the like. The file system manages files generated by a user application (or an operating system). The device driver handles an interface between the storage device 200 and a user application and/or an operating system. The file system and the device driver may be stored as software.

The file system of the host 100 may receive a request for a file write or a request for a file read from a user application. The file system may store a file in the storage device 100 or read a file from the storage device 200, in response to a request of a user application.

When the file system stores a file in the storage device 200, file data and metadata may be stored in the data storage unit 210. The file data includes content of a file which a user application desires to store, and the metadata includes an attribute of the file and the location of a block where the file data is to be stored. When the file system reads a file from the storage device 200, stored metadata is read from the data storage unit 210, and then file data is read based on the read metadata.

In order to completely discharge internal operating power supplies of the storage device 200 to a ground voltage level when a power supply of the storage device 200 is turned off, the controller 220 may include a forced discharge circuit 300. The forced discharge circuit 300 rapidly discharges the internal operating power supplies of the storage device 200 to the ground voltage level by using the highest voltage of the storage device 200. The forced discharge circuit 300 may limit the amount of current that flows from an internal operating power supply to a ground node by using a resistor connected to the internal operating power supply. According to some embodiments, the forced discharge circuit 300 may be disposed outside the controller 220.

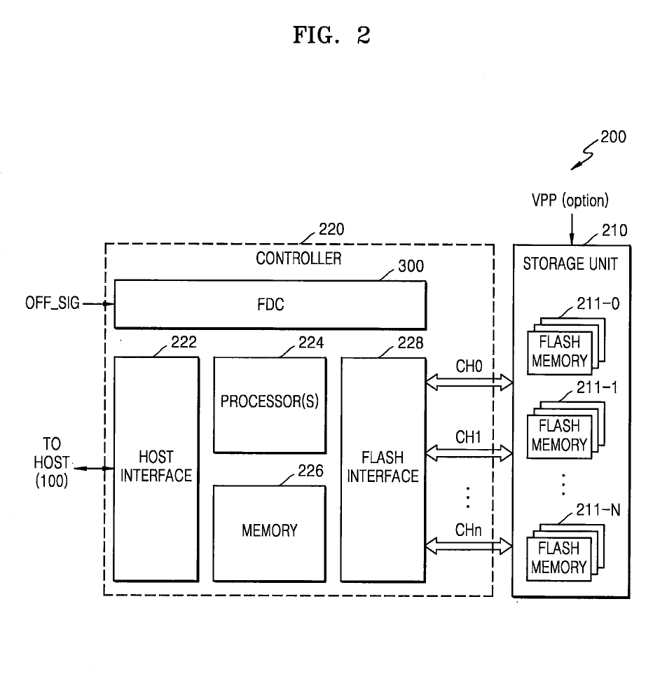

FIG. 2 is a block diagram of a storage device 200 including a forced discharge circuit, according to some embodiments of the inventive subject matter. The storage device 200 may include an SSD that is a flash-based storage system, and may include a data storage unit 210 and a controller 220 (hereinafter, the storage device 200 will be referred to as an SSD for convenience of explanation). The data storage unit 210 may include a non-volatile memory, such as a flash memory. The data storage unit 210 may optionally receive a high voltage VPP from an external source. The high voltage VPP has the highest voltage level among voltages that are used in the data storage unit 210. For example, the high voltage VPP may be a delete voltage that is used for a delete operation of a flash memory.

The controller 220 may include a host interface 222, a processor 224, a memory 226, a flash interface 228, and a forced discharge circuit 300. According to some embodiments, the forced discharge circuit 300 may not be included in the controller 220, but may be disposed outside the controller 220.

One or more channels, for example, N channels CH0 to CH(N−1) (wherein N is an integer that is equal to or greater than 1), may be provided between the data storage unit 210 and the controller 220. Respective flash memories 211-0 to 211-N may be electrically connected to the channels CH0 to CH(N−1). The plurality of flash memories 211-0 to 211-N may form a plurality of ways. The channels CH0 to CH(N−1) denote an independent bus for transmitting a command and data to flash memories 211-0 to 211-N corresponding thereto. Each way denotes a set of flash memories 211-0 to 211-N that share one channel.

According to some embodiments, the same types of memories may be connected to one of the plurality of channels CH0 to CH(N−1), and different types of memories or the same types of memories may be connected to the other channels.

The flash memories 211-0 to 211-N forming the data storage unit 210 are memories into which data cannot be overwritten. A delete operation has to be performed in advance in order to re-write data to the flash memories 211₀ to 211_{N}. The unit of data that is written into the flash memories 211₀ to 211_{N} is different from that of data that is deleted from the flash memories 211₀ to 211_{N}. In the flash memories 211-0 to 211-N, a write operation may be performed by units of pages and a delete operation may be performed by units of blocks. Each block may include a plurality of pages. In other words, the unit of data that is written into the flash memories 211-0 to 211-N is smaller than that of data that is deleted from the flash memories 211-0 to 211-N.

A flash translation layer (FTL) is used between a file system of the host 100 and the flash memories 211-0 to 211-N to hide delete operations of the flash memories 211-0 to 211-N. The FTL maps a logical block address (LBA) generated by a file system during a write operation for the flash memories 211-0 to 211-N to a physical block address (PBA) of the flash memories 211-0 to 211-N for which a delete operation has been performed. Due to an address mapping function of the FTL, the host 100 may determine that the SSD 200 including the flash memories 211-0 to 211-N is a hard disk drive, and may access the flash memories 211-0 to 211-N in the same manner as the hard disk drive.

The flash memories 211-0 to 211-N may perform a delete operation by using a high voltage VPP that is provided from a source external to the data storage unit 210. According to some embodiments, the high voltage VPP may be provided by a voltage generator in each of the flash memories 211-0 to 211-N. The high voltage VPP is a voltage having the highest voltage level among operating voltages of the flash memories 211-0 to 211-N. Examples of the operating voltages of the flash memories 211-0 to 211-N may include a program voltage, a read voltage, a verification voltage, and an internal power supply voltage.

The host interface 222 interfaces data exchange between the host 100 and the data storage system 200, connected via a high-speed bus. The bus format of the host interface 222 may include, for example, USB, SCSI, PCI-E, ATA, PATA, SATA, or SAS. The host interface 222 receives a control command or data from the host 100. Also, the host interface 222 transmits the control command or data output from the host 100 to the processor 224 via an internal bus.

The processor 224 controls an overall operation of the SSD 200. The processor 224 controls data exchange between the host 100 and the host interface. The processor 224 controls an overall operation of the SSD 200 so as to perform an operation responsive to a control command output from the host 100. The processor 224 receives a control command or data from the host 100 via an internal bus. The processor 224 may control the SSD 200 to store data corresponding to a control command in the memory 226 or the flash memories 211-0 to 211-N.

The processor 224 may transmit a control command for data storage or data to the flash interface 228 to store data in the flash memories 211-0 to 211-N. Data corresponding to a control command of the processor 224 may be stored in the flash memories 211-0 to 211-N via the flash interface 228.

The memory 226 is a temporary storage space and stores various pieces of data for an arithmetic operation of an SSD control program that is executed by the processor 224. The processor 224 may store a control command or data output from the host 100 in the memory 226. The memory 226 may include a non-volatile memory (e.g., boot ROM) that may store a program code for controlling an operation of the processor 224, and may include a volatile memory (e.g., DRAM or SRAM) that may store data that is sent or received between the host 100 and the processor 224. In this case, DRAM may be used as a cache memory or a write buffer memory.

The memory 226 may serve as a buffer memory for temporarily storing write data provided from the host 100 or data read from the flash memories 211-0 to 211-N. When data in the flash memories 211-0 to 211-N is cached when the host 100 requests a read operation, the memory 226 supports a cache function of directly providing cached data to the host 100. In general, a data transmission speed by a bus format (e.g., SATA or SAS) of the host 100 is significantly greater than a transmission speed of a memory channel of the SSD 200. In other words, when an interface speed of the host 100 is relatively fast, the memory 226 may minimize degrading performance due to a speed difference by providing a large buffer memory space.

When a main power supply voltage of the SSD 200 is unstable, the forced discharge circuit 300 completely discharges internal operating power supplies of the SSD 200 to the level of the ground voltage VSS by using the high voltage VPP. When the internal operating power supplies of the SSD 200 are completely discharged to the level of the ground voltage VSS, the internal operating power supplies may be generated to have stable voltage levels through an operation of a power management integrated circuit (PMIC) when the power supply of the SSD 200 is turned on again. Accordingly, the SSD 200 may stably operate.

Hereafter, various embodiments of the forced discharge circuit 300 are described in detail.

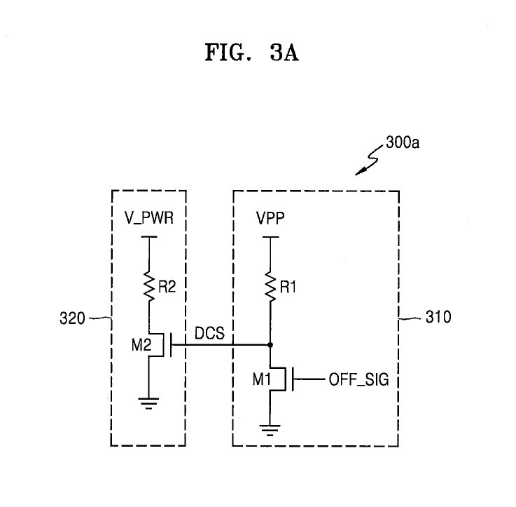

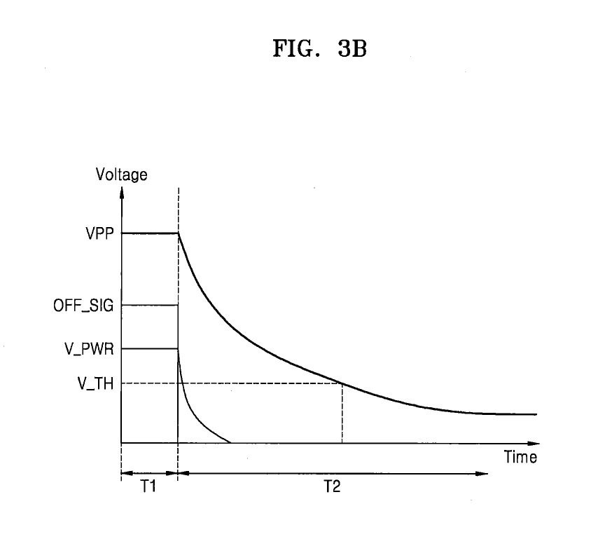

FIGS. 3A and 3B are diagrams illustrating a forced discharge circuit 300a according to some embodiments of the inventive subject matter. FIG. 3A is a circuit diagram of the forced discharge circuit 300a, and FIG. 3B is an operation graph of the forced discharge circuit 300a.

Referring to FIG. 3A, the forced discharge circuit 300a includes a discharge control signal generator 310 and a discharge circuit 320. The discharge control signal generator 310 is driven by a high voltage VPP, and generates a discharge control signal DCS in response to a power-off signal OFF_SIG. The discharge control signal generator 310 may include a first resistor R1 connected between the high voltage VPP and the discharge control signal DCS, and a first transistor M1 connected between the discharge control signal DCS and the ground voltage VSS. The first transistor M1 may be an NMOS transistor that is controlled by the power-off signal OFF_SIG.

The power-off signal OFF_SIG is a signal that is generated when a main power supply voltage VDD of the SSD 200 of FIG. 2 decreases to a predetermined voltage level or less. When a power supply of the SSD 200 is intentionally turned off by a user or is unexpectedly turned off regardless of the intention of a user, the main power supply voltage VDD of the SSD may be decreased.

The power-off signal OFF_SIG may, for example, be provided from a PMIC that generates an internal operating power supply V_PWR based on the main power supply voltage VDD of the SSD 200.

According to some embodiments, the power-off signal OFF_SIG may be provided from a voltage detector that detects a dropped voltage level when a level of the main power supply voltage VDD has been decreased in the processor 224 of the SSD 200.

In other exemplary embodiments, the power-off signal OFF_SIG may be provided from a comparator that is a separate element outside the SSD 200. The comparator may generate the power-off signal OFF_SIG by using an operational amplifier that receives the main power supply voltage VDD and a reference voltage. The power-off signal OFF_SIG may be generated at a logic high level when the main power supply voltage VDD has a normal voltage level, and may be generated at a logic low level when the main power supply voltage VDD decreases to a predetermined voltage level or less.

The discharge control signal generator 310 may generate the discharge control signal DCS at a logic low level when the first transistor M1 is turned on in response to the power-off signal OFF_SIG at a logic high level. The discharge control signal generator 310 may generate the discharge control signal DCS at a logic high level when the first transistor M1 is turned off in response to the power-off signal OFF_SIG at a logic low level. The discharge control signal DCS at a logic high level has a voltage level of the high voltage VPP.

The discharge circuit 320 discharges the voltage level of the internal operating power supply V_PWR to the level of the ground voltage VSS in response to the discharge control signal DCS. The discharge circuit 320 may include a second resistor R2 connected to the internal operating power supply V_PWR and a second transistor M2 connected between the second resistor R2 and the ground voltage VSS. The second transistor M2 may be an NMOS transistor that is controlled by the discharge control signal DCS.

In the discharge circuit 32, the amount of current flowing through the second resistor R2 may be varied by adjusting the resistance value of the second resistor R2 based on the voltage level of the internal operating power supply V_PWR. The current flowing through the second resistor R2 is provided to the second transistor M2, and thus becomes a current of the second transistor M2. When an excessive current flows through the second transistor M2, the second transistor M2 may be damaged. In order to protect the second transistor M2, the current flowing through the second transistor M2 may be limited by the second resistor R2.

In the discharge circuit 320, the second transistor M2 is turned off in response to the discharge control signal DCS at a logic low level and thus a current path from the internal operating power supply V_PWR to the ground voltage VSS is blocked. This means that when the main power supply voltage VDD is in a stable state, the discharge control signal DCS is generated at a logic low level according to a logic high level of the power-off signal OFF_SIG, a discharge path of the internal operating power supply V_PWR is blocked, and thus, the internal operating power supply V_PWR maintains a stable voltage level.

In the discharge circuit 320, the second transistor M2 is turned on in response to the discharge control signal DCS at a logic high level and thus a current path from the internal operating power supply V_PWR to the ground voltage VSS is formed. This means that when the main power supply voltage VDD decreases to a predetermined voltage level or less, the discharge control signal DCS is generated at a logic high level according to a logic low level of the power-off signal OFF_SIG, a discharge path from the internal operating power supply V_PWR to the ground voltage VSS is formed, and thus, the internal operating power supply V_PWR is discharged to the ground voltage VSS. In other words, when the main power supply voltage VDD is in an unstable state in which the main power supply voltage VDD decreases to a predetermined voltage level or less, the discharge circuit 320 quickly discharges the internal operating power supply V_PWR to the ground voltage VSS.

Referring to FIGS. 3A and 3B, in a period T1 in which the main power supply voltage VDD is stable, each of the high voltage VPP and the internal operating power supply V_PWR maintains a constant voltage level. The high voltage VPP has a voltage level that is higher than the internal operating power supply V_PWR. For example, the high voltage VPP may have a voltage level of about 12 volts (V), and the internal operating power supply V_PWR may have a voltage level of about 1.8V. It is assumed that the main power supply voltage VDD has a voltage level of about 5V. Voltage levels of the high voltage VPP, the internal operating power supply V_PWR, and the main power supply voltage VDD may be changed to various voltage levels according to exemplary embodiments.

In the period T1, the power-off signal OFF_SIG has a logic high level when the main power supply voltage VDD is in a stable state. When the power-off signal OFF_SIG is provided from a PMIC, the power-off signal OFF_SIG at a logic high level has the same voltage level as the main power supply voltage VDD of the PMIC.

In a period T2 in which the main power supply voltage VDD is unstable, the power-off signal OFF_SIG transitions to a logic low level of the ground voltage VSS. As an example, it is assumed that when the main power supply voltage VDD of 5V decreases to 3.6V, the main power supply voltage VDD is unstable.

In the period T2, the high voltage VPP and the internal operating power supply V_PWR start to be discharged and voltage levels thereof are decreased. The high voltage VPP is discharged from the highest voltage level, and thus, the voltage level of the high voltage VPP becomes equal to that of the discharge control signal DCS as the first transistor M1 of the discharge control signal generator 310 is turned off by the power-off signal OFF_SIG at a logic low level.

The second transistor M2 of the discharge circuit 320 is turned on by the discharge control signal DCS having a voltage level that is equal to the voltage level of the high voltage VPP that is discharged. Accordingly, a current path is formed from the internal operating power supply V_PWR to the ground voltage VSS through the second resistor R2 and the second transistor M2, and thus, the internal operating power supply V_PWR is discharged to the level of the ground voltage VSS.

Before the level of the high voltage VPP is discharged to the level of a threshold voltage V_TH that may turn off the second transistor M2 of the discharge circuit 320, the internal operating power supply V_PWR may be discharged to the level of the ground voltage VSS. In other words, before the current path from the internal operating power supply V_PWR to the ground voltage VSS is blocked, the internal operating power supply V_PWR may be completely discharged to the level of the ground voltage VSS.

As shown in FIG. 3A, when the main power supply voltage VDD of the SSD 200 of FIG. 2 is in an unstable state, the forced discharge circuit 300a completely discharges the internal operating power supply V_PWR to the level of the ground voltage VSS by using the highest voltage VPP. When the internal operating power supply V_PWR is completely discharged to the level of the ground voltage VSS, the internal operating power supply V_PWR may be generated to have a stable voltage level through an operation of a PMIC when the power supply of the SSD 200 is turned on again.

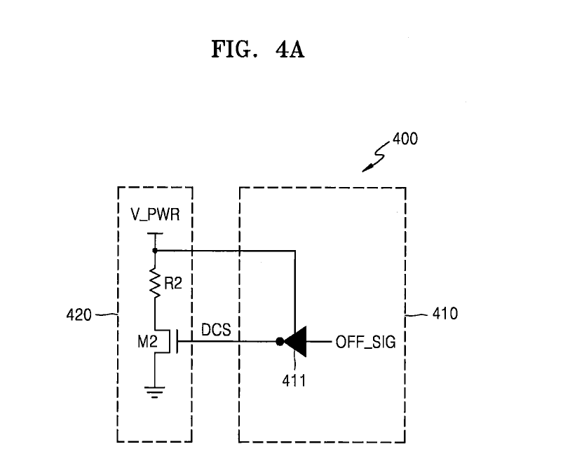

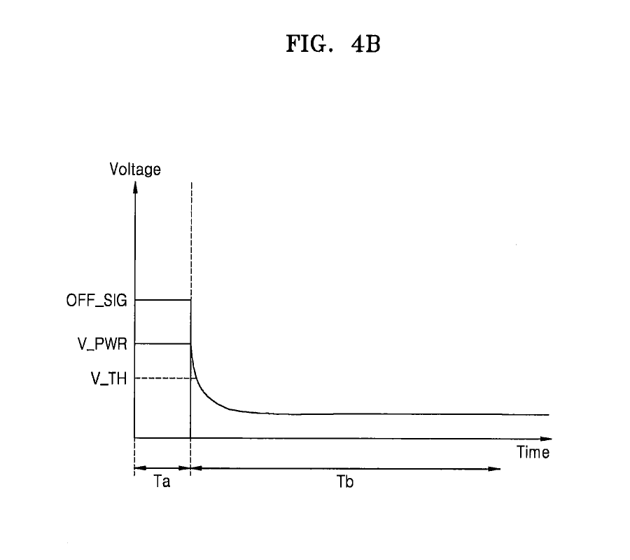

FIGS. 4A and 4B are diagrams illustrating a different forced discharge circuit 400 for comparison with the forced discharge circuit 300a of FIG. 3A. The forced discharge circuit 400 includes a discharge control signal generator 410 and a discharge circuit 420. The discharge control signal generator 410 is driven by an internal operating power supply V_PWR and includes an inverter 411 that receives a power-off signal OFF_SIG and outputs a discharge control signal DCS. The discharge circuit 420 is the same as the discharge circuit 320 of FIG. 3A.

Referring to FIGS. 4A and 4B, in a period Ta in which the main power supply voltage VDD is stable, the internal operating power supply V_PWR maintains a constant voltage level, and the power-off signal OFF_SIG is at a logic high level.

In a period Tb in which the main power supply voltage VDD is unstable, the power-off signal OFF_SIG transitions to a logic low level, and the internal operating power supply V_PWR starts to discharge and thus a voltage level thereof is decreased. The voltage level of the discharge control signal DCS that is an output of the inverter 411 of the discharge control signal generator 410 is increased to a logic high level by the power-off signal OFF_SIG at a logic low level. The voltage level of the discharge control signal DCS at a logic high level becomes equal to that of the internal operating power supply V_PWR that is discharged.

A second transistor M2 of the discharge circuit 420 is turned on by the discharge control signal DCS having a voltage level that is equal to the voltage level of the internal operating power supply V_PWR that is discharged, and thus, a current path may be formed from the internal operating power supply V_PWR to the ground voltage VSS and the internal operating power supply V_PWR may be discharged to the level of the ground voltage VSS.

However, when the voltage level of the internal operating power supply V_PWR is discharged to a level that is equal to or less than a threshold voltage V_TH that may turn off the second transistor M2 of the discharge circuit 420, the current path from the internal operating power supply V_PWR to the ground voltage VSS is blocked. As shown in FIG. 4B, the internal operating power supply V_PWR may not be completely discharged and may have an arbitrary voltage level. When the power supply of the SSD 200 of FIG. 2 is turned on again, the internal operating power supply V_PWR increases to a voltage level other than a set voltage level and thus the SSD 200 may malfunction in an unknown state.

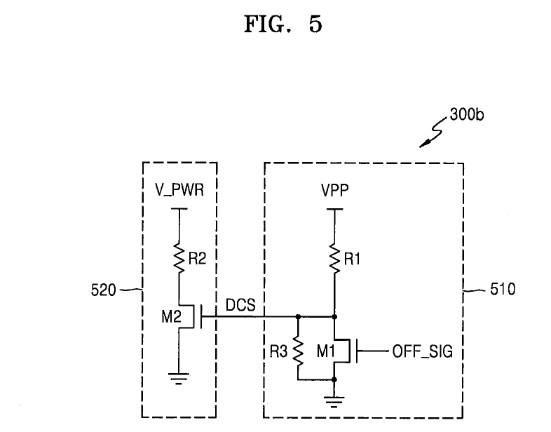

FIG. 5 is a diagram illustrating a forced discharge circuit 300b according to further embodiments of the inventive subject matter. The forced discharge circuit 300b includes a discharge control signal generator 510 and a discharge circuit 520. The discharge control signal generator 510 further includes a third resistor R3 connected between two terminals of a first transistor M1, compared to the discharge control signal generator 310 of FIG. 3A, but is substantially the same as the discharge control signal generator 310 of FIG. 3A.

The third resistor R3 may be used to reduce the likelihood of damage to the first transistor M1 when the voltage level of a high voltage VPP is excessively high. In this case, a first resistor R1 and the third resistor R3 are used as a voltage divider. The first resistor R1 may be connected between the high voltage VPP and a discharge control signal DCS, and the third resistor R3 may be connected between the discharge control signal DCS and the ground voltage VSS.

In the discharge control signal generator 510, when the main power supply voltage VDD is stable, the first transistor M1 is turned on in response to a power-off signal OFF_SIG at a logic high level and thus the discharge control signal DCS at a logic low level may be generated. A second transistor M2 of the discharge circuit 520 is turned off by the discharge control signal DCS at a logic low level, and thus, a current path from an internal operating power supply V_PWR to a ground voltage VSS is blocked. Accordingly, the internal operating power supply V_PWR may maintain a stable voltage level.

When a level of the main power supply voltage VDD decreases to a predetermined voltage level and thus is unstable, the first transistor M1 of the discharge control signal generator 510 is turned off in response to the power-off signal OFF_SIG at a logic low level, and thus, the discharge control signal DCS having a voltage level that is determined according to voltage division by the first and third resistors R1 and R3 may be generated.

When the main power supply voltage VDD is unstable, the high voltage VPP and the internal operating power supply V_PWR also start to be discharged and voltage levels thereof are decreased. The voltage level of the discharge control signal DCS may also be determined according to voltage division by the first and third resistors R1 and R3 based on the high voltage VPP that is discharged. The discharge control signal generator 510 may be designed so that the discharge control signal DCS has a voltage level enough to turn on the second transistor M2 of the discharge circuit 520 even if the level of the high voltage VPP is decreased, through the adjustment of resistance values of the first and third resistors R1 and R3.

The second transistor M2 of the discharge circuit 520 is turned on by the discharge control signal DCS generated based on voltage division of the high voltage VPP that is discharged. Accordingly, a current path from the internal operating power supply V_PWR to the ground voltage VSS is formed and thus the internal operating power supply V_PWR is discharged to the level of the ground voltage VSS.

When the main power supply voltage VDD of the SSD 200 of FIG. 2 is in an unstable state, the forced discharge circuit 300b completely discharges the internal operating power supply V_PWR to the level of the ground voltage VSS by using the highest voltage VPP. When the internal operating power supply V_PWR is completely discharged to the level of the ground voltage VSS, the internal operating power supply V_PWR may be generated to have a stable voltage level through an operation of a PMIC when the power supply of the SSD 200 is turned on again.

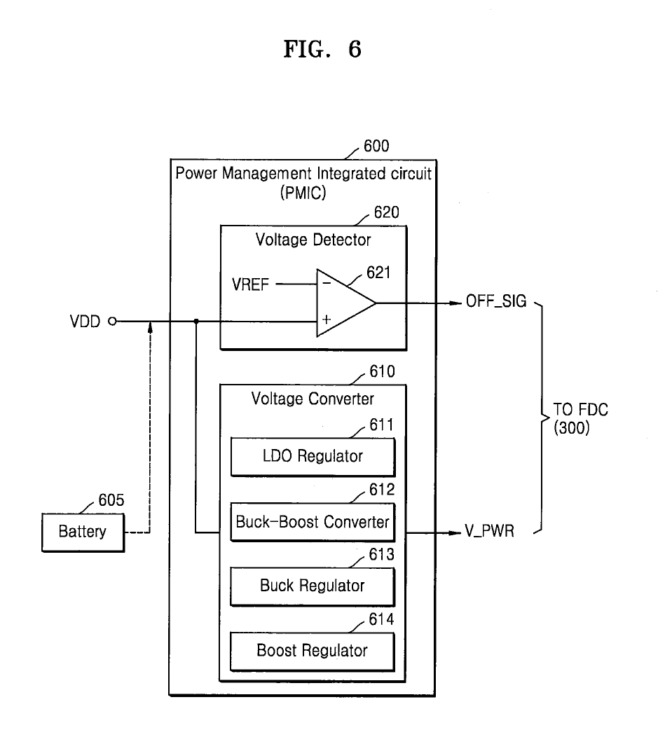

FIG. 6 is a block diagram illustrating a PMIC 600 for generating a power-off signal, according to some embodiments of the inventive subject matter. The PMIC 600 is provided to stably supply power to portable and miniaturized electronic devices. The PMIC 600 may control power, which is supplied to elements of an electronic device, by using technique, such as dynamic voltage frequency scaling (DVFS), clock gating, or power gating.

The PMIC 600 may generate an internal operating power supply V_PWR for elements of the SSD 200 of FIG. 2, for example, for the host interface 222, the processor 224, the memory 226, the flash interface 228, and the flash memories 211-0 to 211-N. Also, the PMIC 600 may generate a power-off signal OFF_SIG when the main power supply voltage VDD of the SSD 200 of FIG. 2 is unstable, and may provide the generated power-off signal OFF_SIG to the forced discharge circuits 300a and 300b of FIGS. 3A and 5.

The PMIC 600 may include a voltage converter 610 and a voltage detector 620. The voltage converter 610 may convert the main power supply voltage VDD into the internal operating power supply V_PWR. The main power supply voltage VDD may be a charging voltage that is provided from a battery 605. The voltage converter 610 may include a low-dropout (LDO) regulator 611, a buck-boost converter 612, a buck regulator 613, and a boost regulator 614.

The LDO regulator 611 is a linear voltage regulator that operates with a very small input-output differential voltage, and may regulate an output voltage of the buck-boost converter 612 to output the internal operating power supply V_PWR. A plurality of LDO regulators 611 may be provided by the number of internal operating power supplies V_PWR that are used in the SSD 200 of FIG. 2.

The buck-boost converter 612 may detect the main power supply voltage VDD, and may operate in a buck-mode when the detected main power supply voltage VDD is higher than the output voltage of the buck-boost converter 612. The buck-boost converter 612 may operate in a boost-mode when the detected main power supply voltage VDD is lower than the output voltage of the buck-boost converter 612, and thus may generate a constant output voltage.

The buck regulator 613 is a voltage reduction-type direct current (DC)/direct current (DC) converter, and may generate a predetermined voltage by reducing an input voltage. The buck regulator 613 may use a switching device that is turned on/off in a certain period, and may have a structure in which an input power supply is connected to a circuit while the switch is turned on and is not connected to the circuit while the switch is turned off. The buck regulator 613 may output a DC voltage by averaging, through an LC filter, a voltage having a pulse shape which is periodically connected to or disconnected from a circuit in this manner. The buck regulator 613 uses a principle of generating an output voltage by averaging a pulse voltage made by periodically chopping a DC voltage, and the output voltage of the buck regulator 613 always has a voltage that is less than an input voltage (i.e., the main power supply voltage VDD) of the buck regulator 613.

The boost regulator 614 is a voltage boost-type DC/DC converter. In the boost regulator 614, when a switch is turned one, the main power supply voltage VDD is connected to two terminals of an inductor and thus a current is charged, and when the switch is turned off, the charge current may be transferred to a load. Accordingly, the amount of current of an output terminal of the boost regulator 614 is always less than that of an input terminal of the boost regulator 614. Since there is no loss due to an operation principle of the boost regulator 614, an output voltage of the boost regulator 614 is higher than an input voltage of the boost regulator 614, based on the relation “input current*input voltage=output current*output voltage”.

The voltage detector 620 detects whether the main power supply voltage VDD is unstable, and generates the power-off signal OFF_SIG based on a result of the detection. The voltage detector 620 may include a comparator 621 that compares the main power supply voltage VDD to a reference voltage VREF and outputs the power-off signal OFF_SIG as a result of the comparison. According to some embodiments, when the main power supply voltage VDD is 5V, the reference voltage VREF may be set to about 3.6V. According to some embodiments, the main power supply voltage VDD and the reference voltage VREF may be set to various voltage levels.

The comparator 621 generates the power-off signal OFF_SIG at a logic high level when the main power supply voltage VDD is higher than the reference voltage VREF, and generates the power-off signal OFF_SIG at a logic low level when the main power supply voltage VDD is lower than the reference voltage VREF. The reference voltage VREF is a criterion for determining whether the main power supply voltage VDD is stable or unstable. When the main power supply voltage VDD is lower than the reference voltage VREF, the voltage detector 620 may determine that the main power supply voltage VDD is unstable.

The internal operating power supply V_PWR and the power-off signal OFF_SIG, generated by the PMIC 600, are provided to the forced discharge circuits 300a and 300b of FIGS. 3A and 5, and the forced discharge circuits 300a and 300b completely discharge the internal operating power supply V_PWR to the level of the ground voltage VSS when the main power supply voltage VDD is unstable.

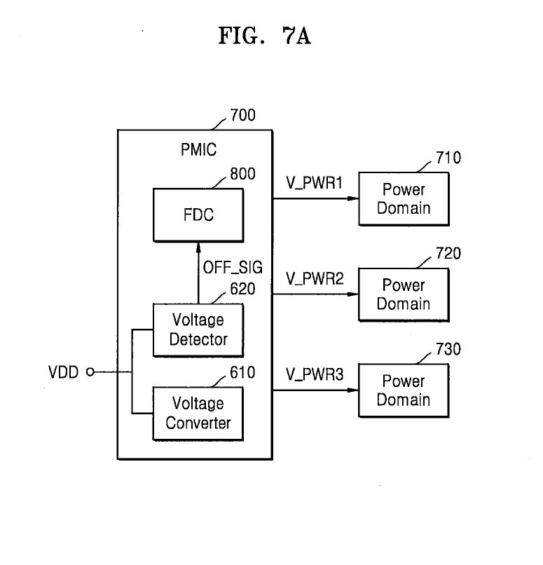

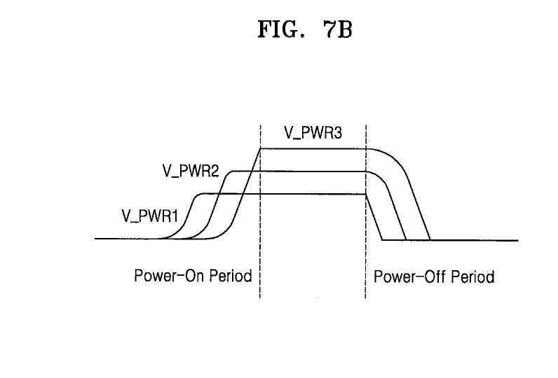

FIGS. 7A and 7B are diagrams illustrating a PMIC 700 including a forced discharge circuit according to some embodiments of the inventive subject matter. The PMIC 700 may generate various operating power supplies (i.e., first through third operating power supplies V_PWR1, V_PWR2, and V_PWR3) of an electronic device and provide the first through third operating power supplies V_PWR1, V_PWR2, and V_PWR3 to power domain blocks 710, 720, and 730 that are driven thereby. The first through third operating power supplies V_PWR1, V-PWR2, and V_PWR3 may be designed to have different voltage levels. For example, among the first through third operating power supplies V_PWR1, V-PWR2, and V_PWR3, the third operating power supply V_PWR3 may have the highest voltage level and the first operating power supply V_PWR1 may have the lowest voltage level.

The PMIC 700 may have a voltage converter 610, a voltage detector 620, and a forced discharge circuit (FDC) 800. The voltage converter 610 may generate the first through third operating power supplies V_PWR1 to V_PWR3 by using the main power supply voltage VDD, as described with reference to FIG. 6. The voltage detector 620 may generate a power-off signal OFF_SIG when the main power supply voltage VDD is unstable.

The first through third operating power supplies V_PWR1 to V_PWR3 may be sequentially generated in a power-on period, as shown in FIG. 7B. Each of the first through third operating power supplies V_PWR1 to V_PWR3 is connected to a capacitor (not shown) of a power domain block 710, 720, or 730 corresponding thereto. Capacitances of the capacitors that are connected to the first through third operating power supplies V_PWR1 to V_PWR3 may be different from each other according to the voltage levels of the first through third operating power supplies V_PWR1 to V_PWR3. For example, the capacitance of a capacitor that is connected to the third operating power supply V_PWR3 having a relatively high voltage may be greater than that of a capacitor that is connected to the first operating power supply V_PWR1 having a relatively low voltage.

The capacitors may be general purpose capacitors or metal to metal (MTM) capacitors and are connected between the first through third operating power supplies V_PWR1 to V_PWR3 and the ground voltage VSS. The capacitors are charged to voltage levels of the first through third operating power supplies V_PWR1 to V_PWR3, respectively, generated by the voltage converter 610. As the capacitors connected to the first through third operating power supplies V_PWR1 to V_PWR3 are charged, the first through third operating power supplies V_PWR1 to V_PWR3 are sequentially generated. The power domain blocks 710, 720, and 730 may be driven by voltage levels of the first through third operating power supplies V_PWR1 to V_PWR3, obtained by the charging of the capacitors.

When the main power supply voltage VDD is unstable, the forced discharge circuit 800 responds to the power-off signal OFF_SIG and completely discharges the first through third operating power supplies V_PWR1 to V_PWR3 to the level of the ground voltage VS S by using the high voltage VPP that is highest from among voltages that are used in the PMIC 700. When the first through third operating power supplies V_PWR1 to V_PWR3 are completely discharged to the level of the ground voltage VSS, the first through third operating power supplies V_PWR1 to V_PWR3 may be generated to have stable voltage levels by an operation of the voltage converter 610 of the PMIC 700 when a power supply of the electronic device is turned on again.

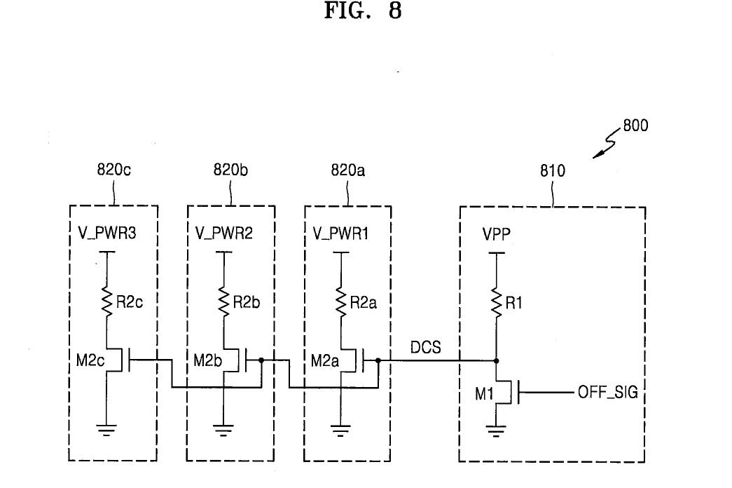

FIG. 8 is a circuit diagram of the forced discharge circuit 800 of FIG. 7. The forced discharge circuit 800 includes a discharge control signal generator 810 and first through third discharge circuits 820a to 820c. The forced discharge circuit 800 further includes the second discharge circuit 820b connected between the second operating power supply V_PWR2 and the ground voltage VSS and the third discharge circuit 820b connected between the third operating power supply V_PWR3 and the ground voltage VSS, compared to the forced discharge circuit 300a of FIG. 3A, and is substantially the same as the forced discharge circuit 300a of FIG. 3A.

The discharge control signal generator 810 is driven by the high voltage VPP and generates the discharge control signal DCS in response to the power-off signal OFF_SIG. When the main power supply voltage VDD is stable, a first transistor M1 of the discharge control signal generator 810 is turned on in response to the power-off signal OFF_SIG at a logic high level, and thus, the discharge control signal DCS at a logic low level may be generated. When the main power supply voltage VDD is unstable, the first transistor M1 of the discharge control signal generator 810 is turned off in response to the power-off signal OFF_SIG at a logic low level, and thus, the discharge control signal DCS at a logic high level may be generated. The discharge control signal DCS at a logic high level has the same voltage level as the high voltage VPP.

When the main power supply voltage VDD is stable, a second transistor M2a of the first discharge circuit 820a is turned off in response to the discharge control signal DCS at a logic low level, and thus, a current path from the first operating power supply V_PWR1 to the ground voltage VSS is blocked.

When the main power supply voltage VDD decreases to a predetermined voltage level and thus is unstable, the second transistor M2a of the first discharge circuit 820a is turned on in response to the discharge control signal DCS at a logic high level, and thus, a current path from the first operating power supply V_PWR1 to the ground voltage VSS is formed. When the main power supply voltage VDD is unstable, the high voltage VPP and the internal operating power supply V_PWR also start to be discharged and voltage levels thereof are decreased. However, before the level of the high voltage VPP is discharged to the level of a threshold voltage V_TH that may turn off the second transistor M2a of the first discharge circuit 820a, the level of the first internal operating power supply V_PWR1 may be discharged to the level of the ground voltage VSS.

The second discharge circuit 820b may include a third resistor R2b connected to the second operating power supply V_PWR2 and a third transistor M2b connected between the third resistor R2b and the ground voltage VSS. The third transistor M2b is controlled by the discharge control signal DCS. The second discharge circuit 820b may limit a current, which flows through the third transistor M2b, by adjusting the resistance of the third resistor R2b according to the voltage level of the second operating power supply V_PWR2. The second discharge circuit 820b may discharge the second operating power supply V_PWR2 to the ground voltage VSS in response to the discharge control signal DCS.

When the main power supply voltage VDD is stable, the third transistor M2b of the second discharge circuit 820b is turned off in response to the discharge control signal DCS at a logic low level, and thus, a current path from the second operating power supply V_PWR2 to the ground voltage VSS is blocked.

When the main power supply voltage VDD decreases to a predetermined voltage level and thus is unstable, the third transistor M2b of the second discharge circuit 820b is turned on in response to the discharge control signal DCS at the level of the high voltage VPP, and thus, the voltage level of the second internal power supply V_PWR2 may be discharged to the level of the ground voltage VSS.

The third discharge circuit 820c may include a fourth resistor R2c connected to the third operating power supply V_PWR3 and a fourth transistor M2c connected between the fourth resistor R2c and the ground voltage VSS. The fourth transistor M2c is controlled by the discharge control signal DCS. The third discharge circuit 820c may limit a current, which flows through the fourth transistor M2c, by adjusting the resistance of the fourth resistor R2c according to the voltage level of the third operating power supply V_PWR3. The third discharge circuit 820c may discharge the third operating power supply V_PWR3 to the ground voltage VSS in response to the discharge control signal DCS.

When the main power supply voltage VDD is stable, the fourth transistor M2c of the third discharge circuit 820c is turned off in response to the discharge control signal DCS at a logic low level, and thus, a current path from the third operating power supply V_PWR3 to the ground voltage VSS is blocked.

When the main power supply voltage VDD decreases to a predetermined voltage level and thus is unstable, the fourth transistor M2c of the third discharge circuit 820c is turned on in response to the discharge control signal DCS at the level of the high voltage VPP, and thus, the voltage level of the third operating power supply V_PWR3 may be discharged to the level of the ground voltage VSS.

When the main power supply voltage VDD is unstable, the first through third operating power supplies V_PWR1 to V_PWR3 may be discharged to the ground voltage VSS in a power-off period, as shown in FIG. 7B. By discharging charges of a capacitor connected to each of the first through third operating power supplies V_PWR1 to V_PWR3, the first through third operating power supplies V_PWR1 to V_PWR3 may be discharged in an order of the first operating power supply V_PWR1, the second operating power supply V_PWR2, and the third operating power supply V_PWR3.

According to some embodiments, the order in which the first through third operating power supplies V_PWR1 to V_PWR3 are discharged may be changed by adjusting the resistances of the first through third resistors R2a to R2c included in the first through third discharge circuits 820a to 820c, respectively. For example, the order may be changed to an order of the third operating power supply V_PWR3, the second operating power supply V_PWR2, and the first operating power supply V_PWR1, or an order of the second operating power supply V_PWR2, the first operating power supply V_PWR1, and the third operating power supply V_PWR3.

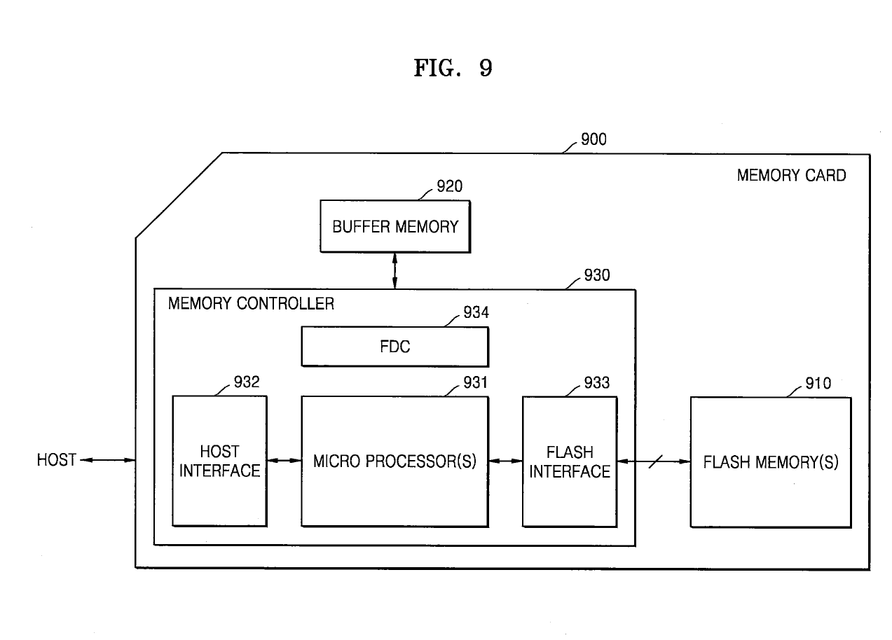

FIG. 9 is a view of a memory card that is an application of a storage device including a forced discharge circuit, according to some embodiments of the inventive subject matter. A memory card 900 includes at least one flash memory device 910, a buffer memory device 920, and a memory controller 930 controlling the flash memory device 910 and the buffer memory device 920. The memory card 900 includes a forced discharge circuit 934 that completely discharges internal operating power supplies to a ground voltage by using a high voltage when a main power supply voltage of the memory card 900 is unstable. The forced discharge circuit 934 may be included in the memory controller 930.

The buffer memory device 920 is a device for temporarily storing data generated during an operation of the memory card 900. The buffer memory device 920 may be realized with DRAM. The memory controller 930 is connected to the flash memory device 910 through a plurality of channels. The memory controller 930 is connected between a host and the flash memory device 910. The memory controller 930 accesses the flash memory device 910 in response to a request from the host.

The memory controller 930 includes at least one microprocessor 931, a host interface 932, and a flash interface 933. The at least one microprocessor 931 may operate firmware. The host interface 932 interfaces with the host through a card protocol, for example, a security digital (SD)/multi-media card (MMC), for performing data exchange between the host and the memory card 900. The memory card 900 may be applied to an MMC, an SD, a miniSD, a memory stick, smart media, a transflash card, and so on.

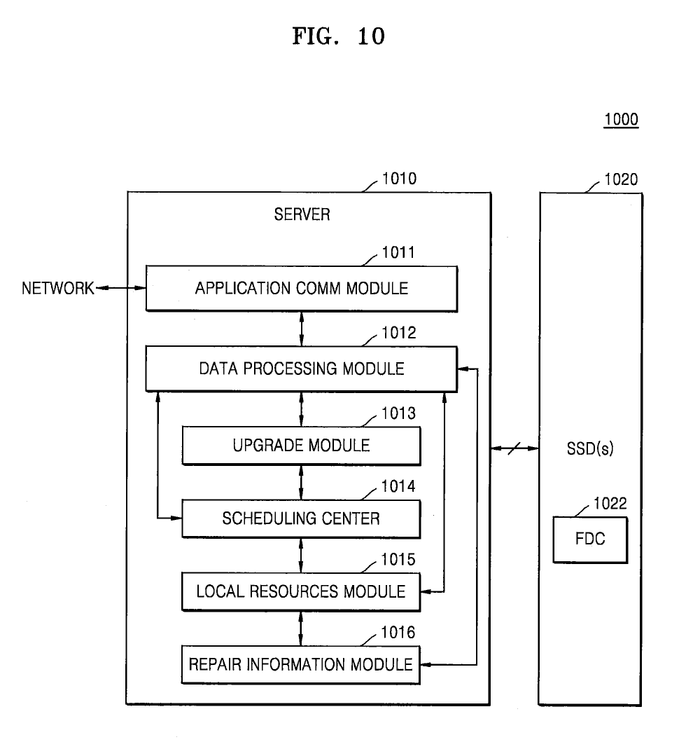

FIG. 10 is a block diagram of a server system 1000 using an SSD that is an application of a storage device including a forced discharge circuit, according to some embodiments of the inventive subject matter. The server system 1000 includes a server 1010 and at least one SSD 1020 that stores necessary data for operating the server 1010. The server 1010 includes an application communication module 1012, a data processing module 1012, an upgrade module 1013, a scheduling center 1014, a local resources module 1015, and a repair information module 1016. The application communication module 1011 is formed to allow the server 1010 to communicate with a computing system connected to a network, or to allow the server 1010 to communicate with the storage device 1020. The application communication module 1011 transmits data or information provided via a user interface to the data processing module 1012.

The data processing module 1012 is linked to the local resources module 1015. The local resources module 1015 provides a list of repair shops/dealers/technical information based on data or information connected to the server 1010. The upgrade module 1013 interfaces with the data processing module 1012. The upgrade module 1013 upgrades firmware, a reset code, a diagnostic system upgrade, or other information of appliances, based on data or information transmitted from the SSD 1020.

The scheduling center 1014 allows a real-time option to a user, based on data or information input to the server 1010. The repair information module 1016 interfaces with the data processing module 1012. The repair information module 1016 is used so as to provide repair-related information, e.g., an audio, a video, or a document file, to a user. The data processing module 1012 packages information, based on information transmitted from the SSD 1020. Afterwards, the information is transmitted to the SSD 1020 or is displayed for the user.

The SSD 1020 includes a forced discharge circuit 1022 that completely discharges an internal operating power supply to a ground voltage by using a high voltage having the highest voltage level in the SSD 1020 when a main power supply voltage of the SSD 1020 is unstable. According to some embodiments, the forced discharge circuit 1022 may be included in the server 1010, and may completely discharge an internal operating power supply to a ground voltage by using a high voltage having the highest voltage level in the server 1010.

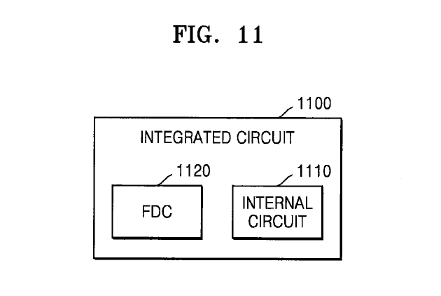

FIG. 11 is a block diagram of an integrated circuit (IC) 1100 including a forced discharge circuit, according to some embodiments of the inventive subject matter. The IC 1100 may include an internal circuit 1110 and a forced discharge circuit 1120. The internal circuit 1110 may perform a specific operation of the IC 1100. The forced discharge circuit 1120 completely discharges an internal operating power supply to a ground voltage by using a high voltage having the highest voltage level in the IC 1100 when a main power supply voltage of the IC 1100 is unstable. When the internal operating power supply is completely discharged to the level of the ground voltage, the internal operating power supply may be generated to have a stable voltage level through an operation of a PMIC when a power supply of the IC 1100 is turned on again. Accordingly, the internal circuit 1110 may stably perform a specific operation.

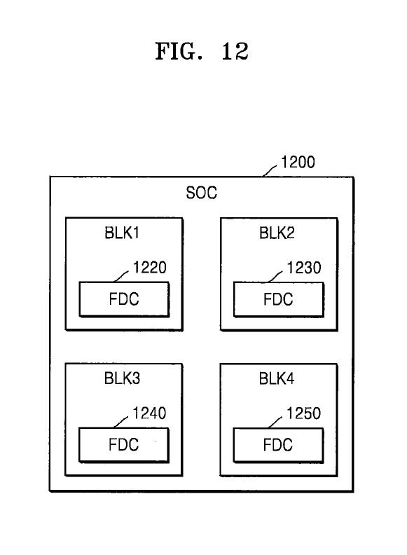

FIG. 12 is a block diagram of a system-on chip (SoC) 1200 including a forced discharge circuit, according to some embodiments of the inventive subject matter. The SoC 1200 may include a plurality of blocks BLK1, BLK2, BLK3, and BLK4, which may be classified from one another according to respective intrinsic functions. Each of the blocks BLK1, BLK2, BLK3, and BLK4 may be one of a core block, a display control block, a file system block, a graphic processing unit (GPU) block, an image signal processing block, and a multi-format codec block, which may include a processor and a memory controller.

According to some embodiments, the SoC 1200 may be an application processor (AP), a microprocessor (MP), a central processing unit (CPU), an application-specific IC (ASIC), a mobile SoC, a multimedia SoC, or an apparatus, device or system similar thereto. The blocks BLK1, BLK2, BLK3, and BLK4 may include forced discharge circuits 1220, 1230, 1240, and 1250, respectively. The forced discharge circuits 1220, 1230, 1240, and 1250 completely discharge internal operating power supplies to a ground voltage by using high voltages having the highest voltage levels in the blocks BLK1, BLK2, BLK3, and BLK4, respectively, when main power supply voltages of the blocks BLK1, BLK2, BLK3, and BLK4 are unstable. When the internal operating power supplies of the blocks BLK1, BLK2, BLK3, and BLK4 are completely discharged to the level of the ground voltage, the internal operating power supplies may be generated to have a stable voltage level through an operation of a PMIC when a power supply of the SoC 1200 is turned on again. Accordingly, the blocks BLK1, BLK2, BLK3, and BLK4 of the SoC 1200 may stably perform their intrinsic functions.

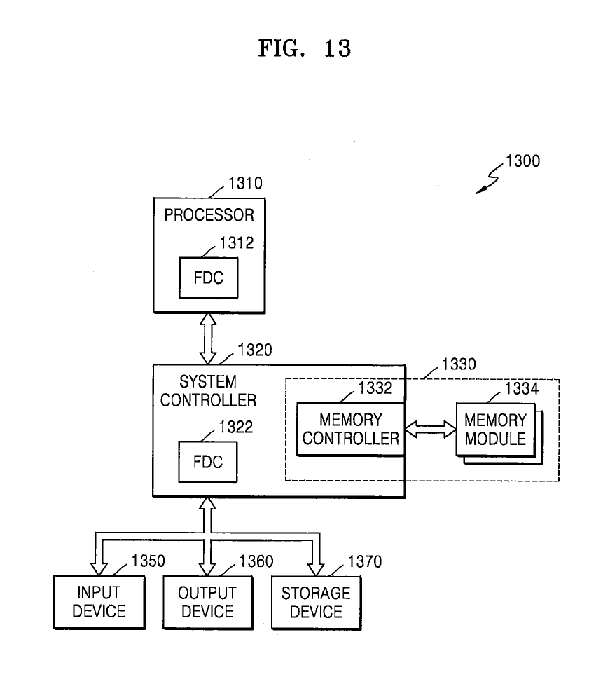

FIG. 13 is a block diagram of a memory system 1300 including a forced discharge circuit, according to some embodiments of the inventive subject matter. The memory system 1300 may include a processor 1310, a system controller 1320, and a memory device 1330. The memory system 1300 may further include an input device 1350, an output device 1360, and a storage device 1370.

The memory device 1330 may include a plurality of memory modules 1334 and a memory controller 1332 configured to control the memory modules 1334. The memory modules 1334 may include at least one volatile memory or non-volatile memory, and the memory controller 1332 may be included in the system controller 1320.

The processor 1310 may perform specific calculations or tasks. The processor 1310 may be connected to the system controller 1320 via a processor bus. The system controller 1320 may be connected to the input device 1350, the output device 1360, and the storage device 1370 via an expansion bus. Thus, the processor 1310 may control the input device 1350, the output device 1360, and the storage device 1370 via the system controller 1320.

The processor 1310 and the system controller 1320 may include forced discharge circuits 1312 and 1322, respectively. The forced discharge circuits 1312 and 1322 completely discharge internal operating power supplies to a ground voltage by using high voltages having the highest voltage levels in the processor 1310 and the system controller 1320, respectively, when main power supply voltages of the processor 1310 and the system controller 1320 are unstable. When the internal operating power supplies of the processor 1310 and the system controller 1320 are completely discharged to the level of the ground voltage, the internal operating power supplies may be generated to have a stable voltage level through an operation of a PMIC when a power supply of the memory system 1300 is turned on again. Accordingly, the processor 1310 and the system controller 1320 of the memory system 1300 may stably perform specific calculations or tasks.

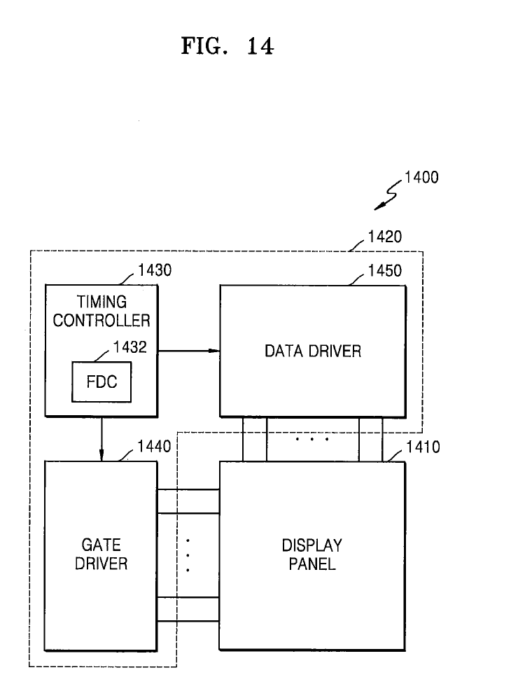

FIG. 14 is a block diagram of a display system 1400 including a forced discharge circuit, according to some embodiments of the inventive subject matter. The display system 1400 may include a display panel 1410 and a display driver integrated circuit (DDI) 1420. The display panel 1410 may include a plurality of gate lines and a plurality of data lines. The display panel 1410 may include a plurality of pixels defined at intersections between the respective gate lines and the data lines. The plurality of pixels may be arranged in a matrix shape and form a pixel array. The display panel 1410 may include an LCD panel, an LED panel, an OLED panel, or a field emission display (FED) panel.

The DDI 1420 may control an operation of the display panel 1410. The DDI 1420 may include a timing controller 1430, a gate driver 1440, and a data driver 1450. The timing controller 1430 may generate a gate driver control signal, a data driver control signal, and data based on an image data signal and a system control signal received from an external source, such as a GPU. The gate driver 1440 may selectively enable gate lines of the display panel 1410 based on the gate driver control signal and select a row of a pixel array.

The data driver 1450 may apply a plurality of driving voltages to the data lines of the display panel 1410 based on the data driver control signal and the data. The display panel 1410 may operate due to operations of the gate driver 1440 and the data driver 1450 and display an image corresponding to the image data signal.

The timing controller 1430 may include a forced discharge circuit 1432. The forced discharge circuit 1422 completely discharges an internal operating power supply to a level of a ground voltage by using a high voltage having the highest voltage level in the timing controller 1430 when a main power supply voltage of the timing controller 1430 is unstable. When the internal operating power supply of the timing controller 1430 is completely discharged to the level of the ground voltage, the internal operating power supply may be generated to have a stable voltage level through an operation of a PMIC when a power supply of the display system 1400 is turned on again. Accordingly, the timing controller 1430 of the display system 1400 may stably generate a gate driver control signal, a data driver control signal, and data.

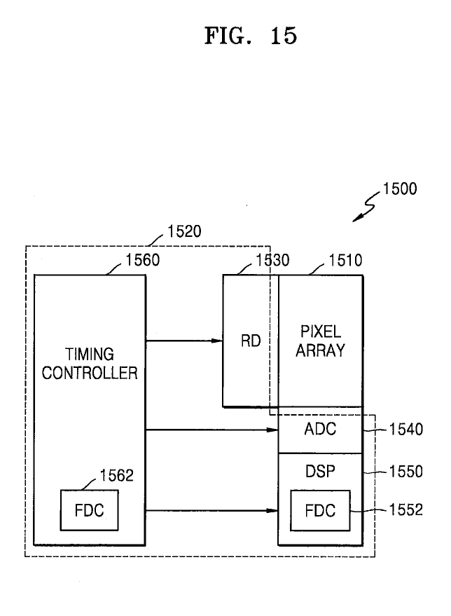

FIG. 15 is a block diagram of an image sensor 1500 including a forced discharge circuit, according to some embodiments of the inventive subject matter. The image sensor 1500 may include a pixel array 1510 and a signal processor 1520. The pixel array 1510 may convert incident light and generate an electric signal. The pixel array 1510 may include a plurality of unit pixels arranged in a matrix shape. The plurality of unit pixels may include color pixels configured to provide color image information and/or distance pixels configured to provide distance information regarding distances to an object (not shown). When the pixel array 1510 includes distance pixels, the image sensor 1500 may further include a light source unit configured to irradiate light to the object.

The signal processor 1520 may process an electric signal and generate image data. The signal processor 1520 may include a row driver (RD) 1530, an analog-to-digital converter (ADC) 1540, a digital signal processor (DSP) 1550, and a timing controller 1560. The row driver 1530 may be connected to each row of the pixel array 1510 and generate a driving signal for driving each row. The ADC 1540 may be connected to each column of the pixel array 1510 and convert an analog signal output from the pixel array 1510 into a digital signal. In some embodiments, the ADC 1540 may include a correlated double sampling (CDS) unit configured to sample a valid signal element. The CDS unit may perform an analog double sampling operation, a digital double sampling operation, or a dual CDS operation for performing both the analog and digital double sampling operations.

The DSP 1550 may receive a digital signal output by the ADC 1540 and perform an image data processing operation on the digital signal. The timing controller 1560 may transmit control signals for controlling the row driver 1530, the ADC 1540, and the DSP 1550.

The DSP 1550 and the timing controller 1560 may include forced discharge circuits 1552 and 1562, respectively. The forced discharge circuits 1552 and 1562 completely discharge internal operating power supplies to a ground voltage by using high voltages having the highest voltage levels in the DSP 1550 and the timing controller 1560, respectively, when main power supply voltages of the DSP 1550 and the timing controller 1560 are unstable. When the internal operating power supplies of the DSP 1550 and the timing controller 1560 are completely discharged to the level of the ground voltage, the internal operating power supplies may be generated to have a stable voltage level through an operation of a PMIC when a power supply of the image sensor 1500 is turned on again. Accordingly, the DSP 1550 and the timing controller 1560 of the image sensor 1500 may stably perform an image data processing.

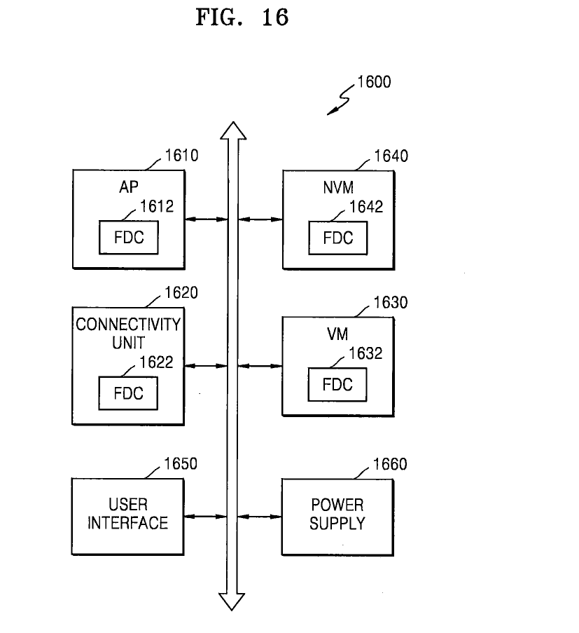

FIG. 16 is a block diagram of a mobile system 1600 using a forced discharge circuit according to some embodiments of the inventive subject matter. The mobile system 1600 may include an application processor (AP) 1610, a communication unit 1620, a volatile memory device 1630, a non-volatile memory device 1640, a user interface 1650, and a power supply 1660. In some embodiments, the mobile system 1600 may be an arbitrary mobile system, such as a mobile phone, a smartphone, a personal digital assistant (PDA), a portable multimedia player (PMP), a digital camera, a music player, a portable game console, or a navigation system.

The AP 1610 may execute applications configured to provide Internet browsers, games, and moving images. In some embodiments, the AP 1610 may include a single core or a multi-core. For example, the AP 1610 may include a multi-core, such as a dual-core, a quad-core, or a hexa-core. In some embodiments, the AP 1610 may further include a cache memory located inside or outside the AP 1610.

The communication unit 1620 may wirelessly communicate with an external device. For example, the communication unit 1620 may perform an Ethernet communication operation, a near-field communication (NFC) operation, a radio-frequency identification (RFID) communication operation, a mobile telecommunication operation, a memory card communication operation, or a universal serial bus (USB) communication operation. For example, the communication unit 1620 may include a baseband chipset and support communications, such as global system for mobile communications (GSM), general packet radio service (GPRS), wideband code division multiple access (WCDMA), and high-speed downlink/uplink packet access (HSxPA).

The volatile memory device 1630 may store data processed by the AP 1610 and operate as a working memory. For example, the volatile memory device 1630 may be embodied by dynamic random access memory (DRAM), static random access memory (SRAM), mobile DRAM, double data rate synchronous dynamic RAM (DDR SDRAM), low-power DDR (LPDDR) SDRAM, graphics DDR (GDDR) SDRAM, Rambus DRAM (RDRAM), or memories similar thereto.

The non-volatile memory device 1640 may store a boot image for booting the mobile system 1600. For example, the non-volatile memory device 1640 may be embodied by electrically erasable programmable read-only memory (EEPROM), flash memory, phase-change RAM (PRAM), resistive RAM (RRAM), nano-floating gate memory (NFGM), polymer RAM (PoRAM), magnetic RAM (MRAM), ferroelectric RAM (FRAM), or memories similar thereto.

The AP 1610, the communication unit 1620, the volatile memory device 1630, and the non-volatile memory device 1640 may include forced discharge circuits 1612, 1622, 1632, and 1642, respectively. The forced discharge circuits 1612, 1622, 1632, and 1642 completely discharge internal operating power supplies to a ground voltage by using high voltages having the highest voltage levels in the AP 1610, the communication unit 1620, the volatile memory device 1630, and the non-volatile memory device 1640, respectively, when main power supply voltages of the AP 1610, the communication unit 1620, the volatile memory device 1630, and the non-volatile memory device 1640 are unstable. When the internal operating power supplies of the AP 1610, the communication unit 1620, the volatile memory device 1630, and the non-volatile memory device 1640 are completely discharged to the level of the ground voltage, the internal operating power supplies may be generated to have a stable voltage level through an operation of a PMIC when a power supply of the mobile system 1600 is turned on again. Accordingly, the AP 1610, the communication unit 1620, the volatile memory device 1630, and the non-volatile memory device 1640 of the mobile system 1600 may stably operate.

The user interface 1650 may include at least one input device (e.g., a keypad or a touch screen) and/or at least one output device (e.g., a speaker or a display device). The power supply 1660 may supply an operating voltage to the mobile system 1600.

In some embodiments, the mobile system 1600 may include a camera image processor (CIS) and further include a storage device, such as a memory card, a solid-state drive (SSD), a hard disk drive (HDD), or CD-ROM. The mobile system 1600 or elements of the mobile system 1600 may be mounted by packages having various shapes. For example, the mobile system 1600 or the elements of the mobile system 1600 may be mounted by using Package on Package (PoP) technique, a ball grid array (BGA) technique, a chip-scale package (CSP) technique, a plastic-leaded chip carrier (PLCC) technique, a plastic dual in-line package (PDIP) technique, a die-in-waffle-pack technique, a die-in-wafer-form technique, a chip-on-board (COB) technique, a ceramic dual in-line package (CERDIP) technique, a plastic metric quad flat-pack (MQFP) technique, a thin quad flat-pack (TQFP) technique, a small outline (SOIC) technique, a shrink small outline package (SSOP) technique, a thin small outline (TSOP) technique, a thin quad flatpack (TQFP) technique, a system-in-package (SIP) technique, a multi-chip package (MCP) technique, a wafer-level fabricated package (WFP) technique, or a wafer-level processed stack package (WSP) technique.

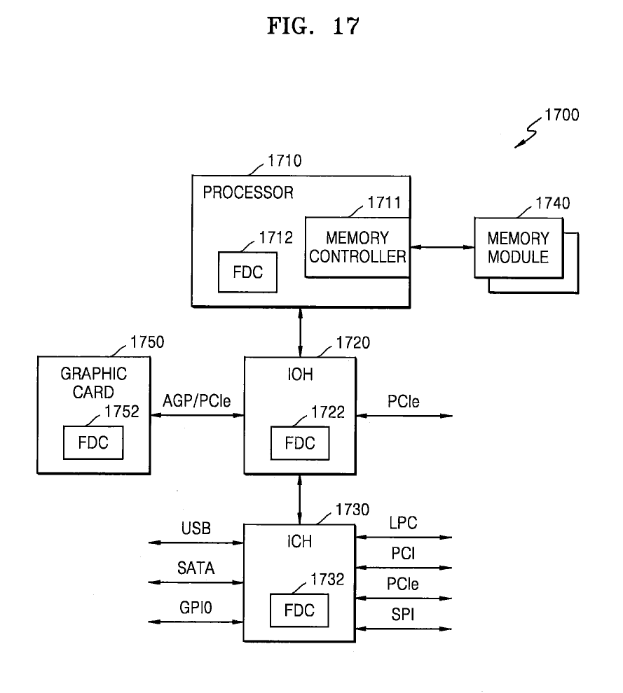

FIG. 17 is a block diagram of a computing system 1700 using a forced discharge circuit according to some embodiments of the inventive subject matter. The computing system 1700 may include a processor 1710, an I/O hub 1720, an I/O controller hub 1730, at least one memory module 1740, and a graphics card 1750. In some embodiments, the computing system 1700 may be an arbitrary computing system, such as a personal computer (PC), a server computer, a work station, a laptop computer, a mobile phone, a smartphone, a personal digital assistant (PDA), a portable multimedia player (PMP), a digital camera, a camcorder, a digital television (digital TV), a set-top box, a music player, a portable game console, and a navigation system.

The processor 1710 may execute various computing functions, such as specific calculations or tasks. For example, the processor 1710 may be a microprocessor (MP) or a central processing unit (CPU). In some embodiments, the processor 1710 may include a single core or a multi-core. In some embodiments, the computing system 1700 may include a plurality of processors. In some embodiments, the processor 1710 may further include a cache memory, which is located inside or outside the processor 1710.

The processor 1710 may include a memory controller 1711 configured to control an operation of the memory module 1740. The memory controller 1711 included in the processor 1710 may be referred to as an integrated memory controller (IMC). A memory interface between the memory controller 1711 and the memory module 1740 may be embodied by a single channel including a plurality of signal lines or embodied by a plurality of channels. At least one memory module 1740 may be connected to each channel. In some embodiments, the memory controller 1711 may be located in the I/O hub 1720. The I/O hub 1720 including the memory controller 1711 may be referred to as a memory controller hub (MCH). The memory module 1740 may include a plurality of volatile or non-volatile memories configured to store provided by the memory controller 1711.

The I/O hub 1720 may manage transmission of data between devices (e.g., the graphics card 1750) and the processor 1710. The I/O hub 1720 may be connected to the processor 1710 through various interfaces. For example, the I/O hub 1720 and the processor 1710 may be connected by various standard interfaces, such as a front side bus (FSB0, a system bus, HyperTransport (HT), a lightning data transport (LDT), QuickPath Interconnect (QPI), or a common system interface (CSI). In some embodiments, the computing system 1700 may include a plurality of I/O hubs.

The I/O hub 1720 may provide various interfaces with devices. For example, the I/O hub 1720 may provide an accelerated graphics port (AGP) interface, a peripheral component interface-express (PCIe), or a communications streaming architecture (CSA) interface.

The graphics card 1750 may be connected to the I/O hub 1720 via an AGP or PCIe. The graphics card 1750 may control a display device to display images. The graphics card 1750 may include an internal processor for processing image data and an internal semiconductor memory device. In some embodiments, the I/O hub 1720 may include a graphics device along with or instead of the graphics card 1750 located outside the I/O hub 1720. The graphics device included in the I/O hub 1720 may be referred to as an integrated graphics. Also, the I/O hub 1720 including a memory controller and the graphics device may be referred to as a graphics and memory controller hub (GMCH).

The I/O controller hub 1730 may perform a data buffering operation and an interface arbitration operation such that various system interfaces may efficiently operate. The I/O controller hub 1730 may be connected to the I/O hub 1720 via an internal bus. For example, the I/O hub 1720 and the I/O controller hub 1730 may be connected by a direct media interface (DMI), a hub interface, an enterprise southbridge interface (ESI), or PCIe.

The I/O controller hub 1730 may provide various interfaces with peripheral devices. For example, the I/O controller hub 1730 may provide a USB port, a SATA port, general-purpose I/O (GPIO), a row pin count (LPC) bus, a serial peripheral interface (SPI), a PCI, or a PCIe.

The processor 1710, the I/O hub 1720, the I/O controller hub 1730, and the graphics card 1750 may include forced discharge circuits 1712, 1722, 1732, and 1752, respectively. The forced discharge circuits 1712, 1722, 1732, and 1752 completely discharge internal operating power supplies to a ground voltage by using high voltages having the highest voltage levels in the processor 1710, the I/O hub 1720, the I/O controller hub 1730, and the graphics card 1750, respectively, when main power supply voltages of the processor 1710, the I/O hub 1720, the I/O controller hub 1730, and the graphics card 1750 are unstable. When the internal operating power supplies of the processor 1710, the I/O hub 1720, the I/O controller hub 1730, and the graphics card 1750 are completely discharged to the level of the ground voltage, the internal operating power supplies may be generated to have a stable voltage level through an operation of a PMIC when a power supply of the computing system 1700 is turned on again. Accordingly, the processor 1710, the I/O hub 1720, the I/O controller hub 1730, and the graphics card 1750 of the computing system 1700 may stably operate.

According to some embodiments, the processor 1710, the I/O hub 1720, and the I/O controller hub 1730 may be embodied by separated chipsets or ICs, respectively. Alternatively, at least two of the processor 1710, the I/O hub 1720, or the I/O controller hub 1730 may be embodied by a single chipset.

While the inventive subject matter has been particularly shown and described with reference to exemplary embodiments thereof, it will be understood that various changes in form and details may be made therein without departing from the spirit and scope of the following claims.

1. An apparatus comprising:
a discharge control signal generator configured to be driven by a first voltage and to generate a discharge control signal in response to a power-off signal; and
a discharge circuit configured to discharge a power supply providing a second voltage less than the first voltage to a level of a ground voltage in response to the discharge control signal,
wherein the first voltage is the highest voltage that is used in an electronic device including the apparatus.

2. The apparatus of claim 1, wherein the first voltage is a program voltage of a flash memory.

3. The apparatus of claim 1, wherein the first voltage is a delete voltage of a flash memory.

4. The apparatus of claim 1, wherein the power-off signal is activated when a main power supply voltage of the electronic device decreases to a predetermined voltage level or less.

5. The apparatus of claim 1, wherein the discharge control signal generator comprises:
a first resistor having a first terminal connected to a node having the first voltage; and
a first transistor connected between a second terminal of the first resistor and a node having the ground voltage and configured to be turned on or turned off in response to the power-off signal.

6. The apparatus of claim 1, wherein the discharge control signal generator comprises:
a first resistor having a first terminal connected to node having the first voltage;
a first transistor connected between a second terminal of the first resistor and a node having the ground voltage and configured to be turned on or turned off in response to the power-off signal; and
a second resistor connected between two terminals of the first transistor.

7. The apparatus of claim 1, wherein the discharge circuit comprises:
a first resistor having a first terminal connected to the power supply; and
a first transistor connected between a second terminal of the first resistor and a node having the ground voltage and configured to be turned on or turned off in response to the discharge control signal.

8. The apparatus of claim 7, wherein the first resistor is changeable to limit a current of the first transistor according to a voltage level of the first operating power supply.

9. The apparatus of claim 7, wherein the power supply comprises a first power supply and wherein the discharge circuit comprises:
a second resistor having a first terminal connected to a second power supply having a voltage greater than the voltage level of the first power supply; and
a second transistor connected between a second terminal of the second resistor and the node having the ground voltage and configured to be turned on or turned off in response to the discharge control signal.

10. The apparatus of claim 9 configured to discharge the second power supply to the ground voltage before the first power supply.

11. An apparatus comprising:
a power management integrated circuit (PMIC) comprising at least one power supply configured to generate at least one power supply voltage from a main power supply and to generate a power-off signal when a level of a voltage of the main power supply decreases to a predetermined voltage level; and
a forced discharge circuit configured to be driven by a first voltage having a voltage level greater than the power supply voltage generated by the at least one power supply and discharge the at least one power supply to a level of a ground voltage in response to the power-off signal.

12. The apparatus of claim 11, wherein the first voltage is provided from the PMIC or is provided from an external source.

13. The apparatus of claim 11, wherein the PMIC compares a level of the voltage of the main power supply to a level of a reference voltage and generates the power-off signal based responsive to the comparing.

14. The apparatus of claim 11, wherein the at least one power supply comprises a first power supply and wherein the forced discharge circuit comprises:
a discharge control signal generator configured to be driven by the first voltage and generate a discharge control signal in response to the power-off signal; and
a first discharge circuit configured to discharge the first power supply to the level of the ground voltage in response to the discharge control signal.

15. The apparatus of claim 14, wherein the discharge control signal generator comprises:
a first resistor having a first terminal connected to a node having the first voltage; and
a first transistor connected between a second terminal of the first resistor and a node having the ground voltage and configured to be turned on or turned off in response to the power-off signal.

16. The apparatus of claim 14, wherein the discharge control signal generator comprises:
a first resistor having a first terminal connected to a node having the first voltage;
a first transistor connected between a second terminal of the first resistor and a node having the ground voltage and configured to be turned on or turned off in response to the power-off signal; and
a second resistor connected between two terminals of the first transistor.

17. The apparatus of claim 14, wherein the first discharge circuit comprises:
a first resistor having a first terminal connected to the power supply; and
a first transistor connected between a second terminal of the first resistor and a node having the ground voltage and configured to be turned on or turned off in response to the discharge control signal.

18. The apparatus of claim 17, wherein the at least one power supply comprises a second power supply producing a voltage greater than a voltage produced by the first power supply and wherein the forced discharge circuit further comprises a second discharge circuit configured to discharge the second power supply to the level of the ground voltage in response to the discharge control signal.

19. The apparatus of claim 18, wherein the first and second power supplies are discharged to the level of the ground voltage in an order of the second power supply and the first power supply.

20. The apparatus of claim 11, wherein the apparatus comprises a flash memory and wherein the first voltage is a delete voltage of the flash memory.

21.-32. (canceled)
